(19) United States
(12) Patent Application Publication
(10) Pub. No.: US 2006/0249652 A1
(43) Pub. Date: Nov. 9, 2006

(54) Methods and systems for pixilation processing of precision, high-speed scanning

(76) Inventor: Kyle Schleifer, San Jose, CA (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/121,560

(22) Filed: May 3, 2005

(51) Int. Cl. H01L 27/00

(52) U.S. Cl. 250/208.1

(57) ABSTRACT

Methods systems and computer readable media for converting a data stream from a precision, high speed scan process into pixel data and accurately locating the pixel data relative to the substrate that was scanned, wherein the substrate is scanned to provide sample signals at a high rate of sampling to form the data stream, including inputting a first or next sample signal from the data stream into an A/D converter and converting the first or next sample signal into a first or next digitized sample signal; inputting the first or next digitized sample signal and a pixel clock signal, in parallel into a digital signal processor or storage buffer wherein the pixel clock signal is adapted to characterize the location of the sample signal relative to the substrate from which it was taken by indicating the transition from one pixel to a next pixel. A multiple storage buffer arrangement is provided for real time analysis of data during scanning. Alternatively the data with pixel signals may be stored in a large buffer for offline analysis.

### BACKGROUND OF THE INVENTION

Precision high speed scanning systems, such as those used for scanning microarrays, for example, require oversampling of the substrate that is being scanned. This oversampling provides a continuous stream of data that must be pixilated based on position to provide an accurate representation of the substrate that was scanned. The more samples per pixel that can be taken during the scan and interpreted by the scanning software, the higher is the signal to noise ratio of the data resulting in the output from the scanner. Due to the non-ideal nature of a motion system different numbers of samples may be taken (and most likely are) for different pixels. This is because pixels are collected based on encoder position (e.g., the physical position of the stage doing the scanning), while inter-pixel samples are collected based on a specific frequency. The stage moving across the substrate (e.g., slide) during scanning, i.e., the motion system, is non-ideal because it cannot be controlled to an absolute velocity. Thus, even if the encoder tics are spaced with absolute precision, the time it takes to pass from one encoder tic to the next will not always be the same and therefore the pixel clock won't always issue time signals at precise time intervals. Of course, it is also impossible to space encoder ticks with absolute precision and this further exacerbates the non-ideal nature of the motion system. Therefore, it cannot be determined how many samples will be taken per pixel, prior to actually carrying out a scan to see the results. The resulting values of these pixels must still be able to be referenced against each other by the system, for accurate positioning and valuation of the pixels that are outputted by the system.

Current systems for performing high speed scanning use a high speed field-programmable gate array (FPGA) to take in the scanned data. An FPGA has fairly limited processing capability and therefore must use very basic pixilation algorithms to combine the data into pixels. This approach is sufficient if there is no need to know information about intra-pixel samples, or if the simple processing algorithms provide sufficiently accurate results. However, a system such as this may also require the use of a digital signal processor (DSP) to carry out more advanced processing of the data once it has been combined by the FPGA into pixels. This increases the complexity and cost of the scanner system.

To reduce such complexity and cost, it would be beneficial to use a high speed digital signal processor (DSP) for pixilation as well as more advanced processing. An approach to this uses the pixel clock (derived from an encoder, for pixilation processing) to trigger an interrupt of the DSP for processing the pixel. For example, the encoder is physically located on the axis of motion on the stage doing the scanning, and feeds to a first DSP that counts the encoder pulses and outputs a pixel clock signal. For example, if the encoder ticks are every 0.1 μm, then the pixel clock may be set for every 5 μm or every 10 μm for the scanner. This approach is problematic however, because even when using one of the fastest DSP's (e.g., faster than 650 MHz) available, it may take anywhere from about one hundred nanoseconds to about three hundred fifty nanoseconds to process an interrupt. In a typical system where a high speed analog to digital (A/D) converter is running at about sixty-five megahertz, the processing time of one hundred nanoseconds to about three hundred fifty nanoseconds equates to a delay of about 6.5 to about 22.75 samples, resulting in the loss of positional accuracy by the DSP.

Accordingly, there are current needs for solutions for precision, high speed scanning systems that use a digital signal processor for pixilation processing. It would further be desirable to provide a system/solution that may employ a digital signal processor for pixilation processing of high speed, precision scan data, as well as for further processing of the data once it has been combined into pixels.

### SUMMARY OF THE INVENTION

Methods systems and computer readable media for converting a data stream from a precision, high speed scan process into pixel data and accurately locating the pixel data relative to the substrate that was scanned, wherein the substrate is scanned to provide sample signals at a high rate of sampling to form the data stream, including inputting a first or next sample signal from the data stream into an A/D converter and converting the first or next sample signal into a first or next digitized sample signal; inputting the first or next digitized sample signal and a pixel clock signal, in parallel into a digital signal processor wherein the pixel clock signal is adapted to characterize the location of the sample signal relative to the substrate from which it was taken by indicating the transition from one pixel to a next pixel; storing the sample signal and pixel clock signal data in digital format as outputted by the A/D converter into a first or second buffer associated with a digital signal processor; repeating said inputting a next sample signal, inputting a pixel clock signal and storing steps until a predetermined percentage of the first or second buffer has been filled; diverting output from the AID converter to the other of the first or second buffer, and repeatedly carrying out inputting of a next sample signal, inputting a pixel clock signal, storing and repeating steps, while, at the same time, processing the stored sample signal and pixel clock digital data stored in the other of the first or second buffers, with the digital signal processor.

Methods, systems and computer readable media for converting a data stream from a precision, high speed scan process into pixel data and accurately locating the pixel data relative to the substrate that was scanned, wherein the substrate is scanned to provide sample signals at a high rate of sampling to form the data stream, including inputting a first or next sample signal from the data stream into an A/D converter and converting the first or next sample signal into a first or next digitized sample signal; inputting the first or next digitized sample signal and a pixel clock signal, in parallel, into a digital signal processor, wherein the pixel clock signal is adapted to characterize the location of the sample signal relative to the substrate from which it was taken by indicating the transition from one pixel to a next pixel; storing the sample signal and pixel clock signal data in digital format as inputted into a buffer associated with a digital signal processor; repeating the inputting and converting a next sample signal, inputting the digitized next sample and a pixel clock signal and storing steps until scanning of the substrate has been completed; and analyzing the stored sample and pixel clock signals by the digital signal processor offline, after scanning has been completed.

Further provided are systems for converting a data stream from a precision, high speed scan process into pixel data and accurately locating the pixel data relative to the substrate that was scanned, wherein the substrate is scanned to provide sample signals at a high rate of sampling to form the data stream, including an A/D converter for high-rate sampling the data stream and converting the samples into digitized sample signals; a pixel clock configured to output a pixel clock signal, in parallel with the digitized sample signals, wherein the pixel clock signal is adapted to characterize the location of the sample signal relative to the substrate from which it was taken by indicating the transition from one pixel to a next pixel; means for storing the sample signal and pixel clock signal data in digital format, wherein the pixel clock signal data is encoded with the sample signal data; and a DSP for analyzing the sample signal data and pixel clock signal data stored in said means for storing.

Methods of forwarding a result, transmitting data representing a result, and/or receiving a result obtained from carrying out any of the methods described herein are also covered by the present invention.

These and other advantages and features of the invention will become apparent to those persons skilled in the art upon reading the details of the systems, methods and computer readable media as more fully described below.

### BRIEF DESCRIPTION OF THE DRAWINGS

FIG. 1 is a schematic representation of analog signals sampled from a substrate during a high speed scanning process, together with data sample clock and pixel clock ticks shown on the time axis to illustrate how sampling is carried out.

FIG. 2 is a schematic representation of a double buffering system that may be used in a system as discussed herein and accessed for digital signal processing.

FIG. 3 schematically illustrates the use of an A/D converter parallel interface for converting analog sample signals to digital data streams and inputting them to a DSP.

FIG. 4 schematically illustrates an arrangement similar to that shown in FIG. 3, and additionally, an alternate gain channel is provided.

FIG. 5 schematically shows signals received from two scans over five pixels of two different substrates, for purposes of explanation of how the system processes different signal intensities.

FIG. 6 shows a data flow diagram to describe an example of processing precision, high speed scanning signals by the present system.

FIG. 7 illustrates conversion of a pixel clock signal from a square wave to an alternative wave by a toggle circuit.

### DETAILED DESCRIPTION OF THE INVENTION

Before the present methods and systems are described, it is to be understood that this invention is not limited to particular hardware, software, methods or method steps described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “and”, and “the” include plural referents unless the context clearly dictates otherwise. Thus, for example, reference to “a DSP” includes a plurality of such DSP's and reference to “the A/D converter” includes reference to one or more A/D converters and equivalents thereof known to those skilled in the art, and so forth.

The publications discussed herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed.

A “microarray”, “bioarray” or “array”, unless a contrary intention appears, includes any one-, two-or three-dimensional arrangement of addressable regions bearing a particular chemical moiety or moieties associated with that region. A microarray is “addressable” in that it has multiple regions of moieties such that a region at a particular predetermined location on the microarray will detect a particular target or class of targets (although a feature may incidentally detect non-targets of that feature). Array features are typically, but need not be, separated by intervening spaces. In the case of an array, the “target” will be referenced as a moiety in a mobile phase, to be detected by probes, which are bound to the substrate at the various regions. However, either of the “target” or “target probes” may be the one, which is to be evaluated by the other.

Methods to fabricate arrays are described in detail in U.S. Pat. Nos. 6,242,266; 6,232,072; 6,180,351; 6,171,797 and 6,323,043. As already mentioned, these references are incorporated herein by reference. Other drop deposition methods can be used for fabrication, as previously described herein. Also, instead of drop deposition methods, photolithographic array fabrication methods may be used. Interfeature areas need not be present particularly when the arrays are made by photolithographic methods as described in those patents.

Following receipt by a user, an array will typically be exposed to a sample and then read. Reading of an array may be accomplished by illuminating the array and reading the location and intensity of resulting fluorescence at multiple regions on each feature of the array. For example, a scanner may be used for this purpose is the AGILENT MICROARRAY SCANNER manufactured by Agilent Technologies, Palo, Alto, Calif. or other similar scanner. Other suitable apparatus and methods are described in U.S. Pat. Nos. 6,518,556; 6,486,457; 6,406,849; 6,371,370; 6,355,921; 6,320,196; 6,251,685 and 6,222,664. Scanning typically produces a scanned image of the array which may be directly inputted to a feature extraction system for direct processing and/or saved in a computer storage device for subsequent processing, or processed in real time as described herein. However, arrays may be read by any other methods or apparatus than the foregoing, other reading methods including other optical techniques or electrical techniques (where each feature is provided with an electrode to detect bonding at that feature in a manner disclosed in U.S. Pat. Nos. 6,251,685, 6,221,583 and elsewhere).

An “FPGA” or “field programmable gate array” as used herein, refers to a programmable logic chip having multiple logic and memory cells that can be programmed by an engineer to perform a specific function.

A “DSP” or “digital signal processor” as used herein, refers to a programmable chip that can take compiled software (or firmware) code and run (execute) it. A DSP is designed as a microprocessor with specialized functions for rapid algorithmic processing.

A “pixel” refers to a signal output representing single or multiple samples input to a system.

An “A/D converter” refers to a device that converts analog voltage into a discrete digital output.

A “register” refers to a designated memory location.

When one item is indicated as being “remote” from another, this is referenced that the two items are at least in different buildings, and may be at least one mile, ten miles, or at least one hundred miles apart.

“Communicating” information references transmitting the data representing that information as electrical signals over a suitable communication channel (for example, a private or public network).

“Forwarding” an item refers to any means of getting that item from one location to the next, whether by physically transporting that item or otherwise (where that is possible) and includes, at least in the case of data, physically transporting a medium carrying the data or communicating the data.

A “processor” references any hardware and/or software combination which will perform the functions required of it. For example, any processor herein may be a programmable digital microprocessor such as available in the form of a mainframe, server, or personal computer. Where the processor is programmable, suitable programming can be communicated from a remote location to the processor, or previously saved in a computer program product. For example, a magnetic or optical disk may carry the programming, and can be read by a suitable disk reader communicating with each processor at its corresponding station.

Reference to a singular item, includes the possibility that there are plural of the same items present.

“May” means optionally.

Methods recited herein may be carried out in any order of the recited events which is logically possible, as well as the recited order of events.

All patents and other references cited in this application, are incorporated into this application by reference except insofar as they may conflict with those of the present application (in which case the present application prevails).

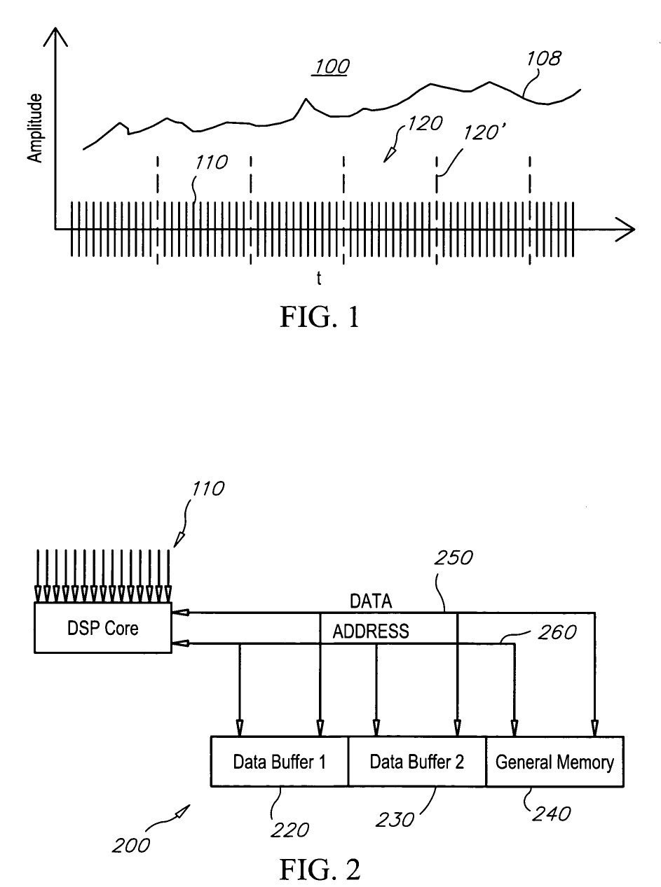

Referring now to FIG. 1, a schematic representation 100 is shown of signals 108 sampled from a substrate during a high speed scanning process. Sampling of the substrate is performed at a very high frequency to provide sample data at sampling intervals indicated by the data sample clock ticks 110. Note that the schematic of FIG. 1 is not drawn to scale and that the sample data clock ticks 110 should appear at equally spaced intervals across the time scale t. The pixels that are constructed from the scanned data to generate an image of the scanned substrate are typically, but not necessarily, significantly larger than the corresponding distance between two sampling data ticks 110. Again, it is noted that FIG. 1 is not drawn to scale, as there would typically be many more sample data ticks 110 per pixel 120 than shown. As one non-limiting example, the linear rate of scanning of a high speed scanning system may be about one meter per second, and the pixel size may be about five microns in length, and this equates to a pixel rate of five microseconds, or two hundred kilohertz. Another pixel length typically used is 10 μm. These two examples give pixel sizes of 25 square microns and 100 square microns, respectively. The sampling rate may be about sixty-five megahertz. Again, this is only an example, but the principle still stands that the sampling rate for such systems may be much faster than the pixilation rate.

The sampled signals must therefore be combined or binned, such as by averaging, processing by some other algorithm, such as a filtering algorithm, trending algorithm or some other algorithm to provide pixel values over the range of each pixel 120 as defined by the pixilation rate relative to the sampling rate. The triggering of the binning to divide one pixel from the next may be initiated by a pixilation clock signal measured by a motor encoder, as noted previously. One difficulty in actually performing this task in real time is that calculations must be performed on the sampled signals as they are inputted to the processor, whether it be an FPGA or a DSP. When the appropriate time is reached to bin a group of sampled signals for combination and representation by a pixel, as measured by a motor encoder, for example, a pixilation clock signal or tick 120′ is sent to the processor to inform the processor of such. The processor must then run one or more additional algorithms to combine the processed sample signals within that bin to generate the resulting pixel information, while still recording raw signals for the next pixel.

As noted above, when processing with an FPGA, it is possible to process the analog to digital converted sample signals 108 in real time, and to convert a binned group of signals to a pixel value in real time as a pixel clock tick 120′ is received by the FPGA. Although an FPGA can rapidly process this data in real time, it nevertheless has limited processing capability, and can only process using very basic pixilation algorithms to combine the data into pixels. For example, as the data is coming in, the FPGA has an accumulator that accumulates the sample signals data as it is coming in, with every clock cycle, in real time. Then, when the pixel clock tick 120′ is received by the FPGA, the FPGA sends out the accumulated value of the binned sample signals 108 for the current pixel, and then begins accumulating sample signal data for the next pixel. However, due to the limited processing capability, the FPGA runs to its limitations just to carry out the accumulation/averaging function in real time, and is unable to do higher level processing of the signal data. For example, given the time constraints, the FPGA is unable to check whether any of the incoming signals are saturated, or to do any filtering of the incoming signals.

When processing with a DSP, in order to get the data into the system as fast as possible in a streaming manner, a double buffering system 200 may be employed, as represented in FIG. 2. Under this arrangement, the DSP Core which contains at least one processor has access and control of first and second data buffers 220 and 230 (i.e., Data Buffer 1 and Data Buffer 2 as shown, or simply referred to as Buffer 1 and Buffer 2) as well as a general memory 240. As sample signals are inputted to the DSP, the DSP Core directs the signals to one or the other of Buffers 1 and 2 via data lines 250 assisted by address lines 260. For example, sample signals 108 are inputted to Buffer 1 until a pixel clock tick 120′ is received by the DSP, after which the sample signals 108 following the pixel clock tick 120′ are inputted to Buffer 2. As sample signals 108 continue to be inputted to Buffer 2, the DSP processes the data in Buffer 1 to generate pixel data. This processing must be sufficiently fast so as to be completed before the next pixel clock tick 120′ is sent to the DSP, as when the next pixel clock tick 120′ is received by the DSP, Buffer 1 is cleared and sample signals 108 which follow are again inputted to Buffer 1 while the DSP processes the data in Buffer 2 to generate pixel data. This allows the data to be continuously inputted, with processing going on concurrently.

A problem with this type of processing is a lack of synchronicity between the pixel clock ticks 120′ and the output of the pixel data. As noted, when a DSP is used to process the sample signals 108, the pixel clock signal 120′ may be used to trigger an interrupt of the DSP, to direct it to process those samples already received into pixel data. This process is also problematic because positional accuracy of the pixel clock signals/ticks 120′ with respect to the sample signals is lost due to the variable amount of time that it takes to process an interrupt, while the reading in of sample signals continues.

In order to correctly correlate the sample signals with the position of the pixel to accurately represent the location on the substrate where the data was taken from, a parallel bus is provided to read in the sample signal data. For example, the parallel bus may be sixteen bit, where the sample signal data is inputted over fourteen bits and one of the additional bits is used to input the pixel clock signal therethrough. By carrying the pixel clock signal concurrently with the sample signal data, the DSP can determine exactly where (i.e., the position of) the data is with respect to the encoder and when the pixel clock signal ticks 120′ occur with respect to the sample signal data 108. Using this arrangement, while the DSP is analyzing data contained within Buffer 1, for example, it analyzes, at the same time, the pixel bit, which encodes the pixel clock information, so that the DSP can determine exactly where the transformations from pixel to pixel have occurred. Note that this double buffering system works somewhat different from the one described above in that a Buffer is not filled until a pixel signal is received, but a Buffer is filled until the Buffer contains a predetermined number of samples, after which filling of the other Buffer resumes while the Buffer containing the predetermined number of samples is analyzed. Further advantageously, processing can be done “off line” (i.e., is not required to be accomplished in real time, in contrast to previous methods described) by storing all of the raw data (including the pixel clock signals) in a single large memory buffer, from which the data can be processed, together with the encode pixel signals, at a later time. Therefore, in contrast to processing with an FPGA which typically runs at its performance limits just to accomplish averaging of the incoming sample data signals into pixels, and nothing more, the present technique permits a much greater extent of processing of the sample data signals, to include checking for saturated signals (as part of processing to extend the dynamic range of the scan), filtering, decision making, etc.

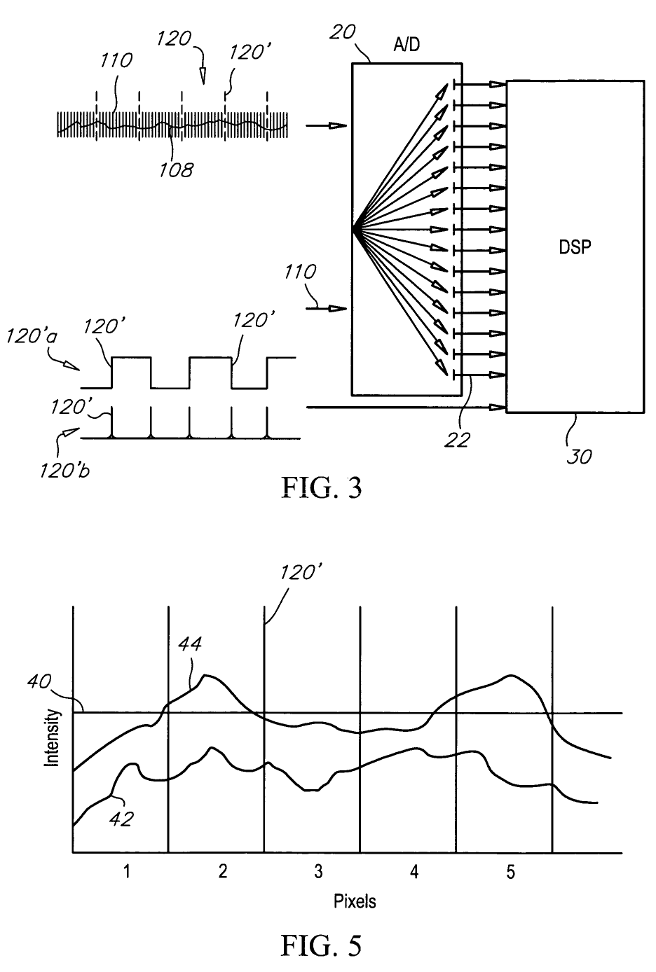

FIG. 3 schematically illustrates the use of an A/D converter 20 having a fourteen bit parallel interface for converting the analog sample signals 108 to digital data streams and inputting them to DSP 30, together with a saturation signal that is outputted via line 22 when a signal is received by the A/D converter that is out of the input range that the A/D converter is capable of accurately converting to a digital signal. Note that the pixel clock signals 120′ shown in phantom and sample clock ticks 110 are shown overlaying the analog signal 108 for the viewer's reference only and are not inputted into the fourteen bits of A/D converter. Rather, analog signal 108 is inputted into the A/D converter 20 and digitized signals are outputted from A/D converter, to be inputted to DSP 30 or Buffers, as noted. The sample clock in inputted to the AID converter to control the sampling rate and digitization of the analog signal 108.

The pixel clock signals 120′ are input through one of the additional bits in the DSP, concurrently with the inputting of the sample signals, so that they are timed exactly with the sample signal data. In this way, DSP 30 can accurately discern the location of the sample signals from which the pixels are generated, by analyzing the pixel clock signals 120′ that are stored concurrently with the sample signal 108 data. FIG. 3 shows two non-limiting examples of pixel clock signals 120′ where signal 120′a is a square wave, with each vertical component of the square wave being a pixel clock tick 120′ that indicates the end of one pixel and start of the next. Similarly, signal 120′b is a flat line signal that generates a spike (with a duration of one sample clock) 110 for each pixel clock tick 120′.

A signal line 22 from A/D converter 20 connects to DSP 30 and is used to signal the DSP when pixel saturation has occurred. If the value of a sample signal 108 being A/D converted exceeds the range of the A/D converter, a signal is inputted from A/D converter 20 to DSP 30 through line 22, concurrently with the digitized signal information that was determined to be saturated, through the fourteen bits, so that DSP 30 can identify the saturated data during further processing. For example, when a saturated signal is identified by the A/D converter 20, the signal through line 22 may change from low to high (0 to 1) or vice versa, to indicate the occurrence of saturation. This speeds up analysis of the signal as the DSP does not have to check for a specific value of the 14 bit data, but instead only has to monitor a 1 bit saturation indicator.

Use of DSP 30 provides the additional processing power that is needed for processing for gain selection, filtering, and other processing that an FPGA does not have sufficient bandwidth for, as alluded to above. A/D converter 20 has a limited input range. For example, when a high speed, high performance scan of a microarray is being performed, a photomultiplier tube may be included in the scanner system to measure photo emissions emitted by the features on the microarray as light is made incident upon them during scanning. An electrometer converts the output of the photomultiplier tube into a voltage input to the A/D converter 20. The speed at which photo emissions are measured and voltage is input to the A/D converter 20 is limited mainly by the bandwidth of the electrometer used. Thus, the speed may range from as fast as a few nanoseconds to as slow as tens of microseconds. The range of the photomultiplier tube (output of the electrometer) exceeds the range of A/D converter 20. Thus, a photo emission may be read by the photomultiplier tube that has an intensity that, when sent to A/D converter, exceeds the range of the A/D converter. This is an example of when the saturation signal is tripped and inputted through line 22, as described above.

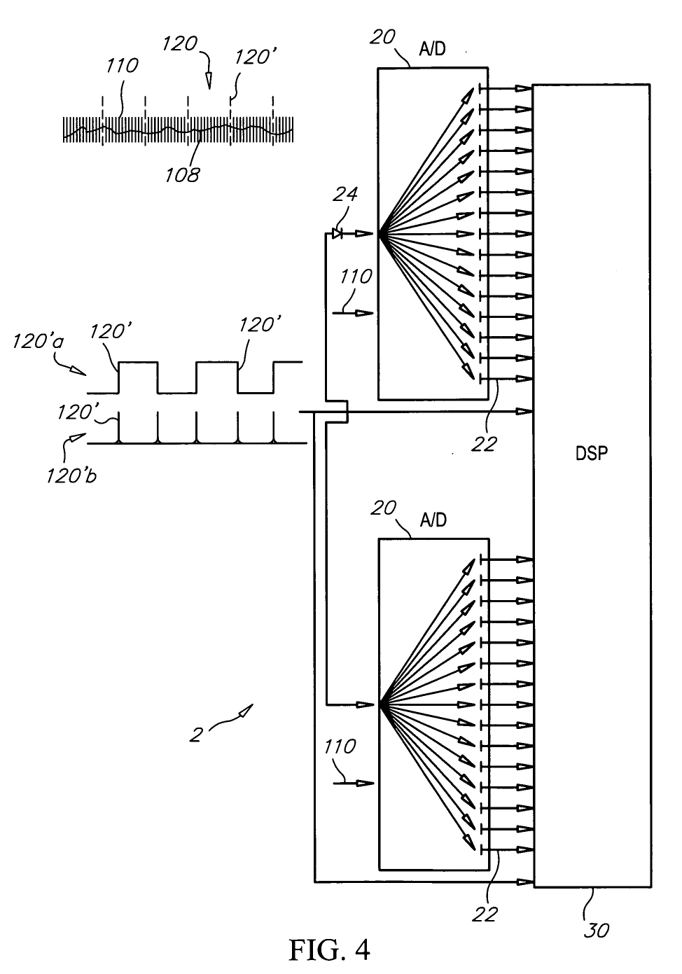

In order to extend the dynamic range of the scanning system, an extra gain channel 2 may be provided to connect an additional A/D converter 20 to the DSP 30 through alternate gain channel 2, as shown in FIG. 4. This arrangement maintains the lower range of sensitivity of the dynamic range through the primary gain channel 1 (top A/D converter shown) through amplifier 24. However, when DSP 30 detects that a sample signal 108 is saturated, as indicated by the signal 22 received from the primary gain channel 1 (top A/D converter 20 shown), the DSP is programmed to consider the same signals for that pixel from the alternate gain channel 2 (lower A/D converter 20 shown in FIG. 4) that is not amplified in the manner shown for channel 1, so that this channel has lower sensitivity. Thus, the default is toward higher sensitivity, but, when saturated, the secondary channel 2, having less sensitivity, is used. In the very unlikely occurrence where a signal is determined to be saturated also in channel 2, by a signal 22 received from alternate gain channel 2, then the DSP can raise a flag that indicates that the range has exceeded all gain channels and therefore the data from the saturated signal isn't valid. Thus, by processing the signals from the primary gain channel 1 for pixels that are not saturated, and processing the pixels that contain at least one signal that is saturated in the primary channel 1 (first (top) A/D converter 20) from the alternate gain channel 2 (second (bottom) A/D converter shown) where they are not saturated, the DSP can output a wider range of dynamic response before reaching saturation levels, thereby increasing the fidelity and accuracy of the scan. It should be noted that the arrangement is not limited to only two alternative gain channels, as more alternative gain channels may be provided similarly, to provide the capability for an even wider overall bandwidth of sensitivity. However, if more than two A/D converters are provided for more than two gain channels, more than one DSP may be needed to handle the processing requirements. However, there are available DSP's (from Analog Devices, for example) that can take in data from up to four A/D converters. Further details regarding the processing of signals to correct for saturated values can be found in application Ser. No. 10/912,661 filed on Aug. 4, 2004, and titled “Methods and Compositions for Assessing Partially Saturated Pixel Signals.” application Ser. No. 10/912,661 is hereby incorporated herein, in its entirety, by reference thereto.

FIG. 5 schematically shows signals 42, 44 received from two scans over five pixels of two different substrates, for purposes of explanation of how the system processes different signal intensities. Line 40 indicates the cutoff intensity, that is the intensity value at which gain channel 1 is considered to be saturated. For scan signal 42, it can be seen that none of the intensities of the sample signals within any of the pixels exceeds the intensity saturation level 40. Accordingly, all pixels for the scan signal 42 are processed from the primary gain channel (gain channel 1). However, with regard to scan signal 44, some intensity values within pixels 1, 2, 4 and 5 exceed the intensity saturation level 40, In this example, pixel 3 is processed from the primary gain channel data, while pixels 1, 2, 4 and 5 are processed from the secondary gain channel data.

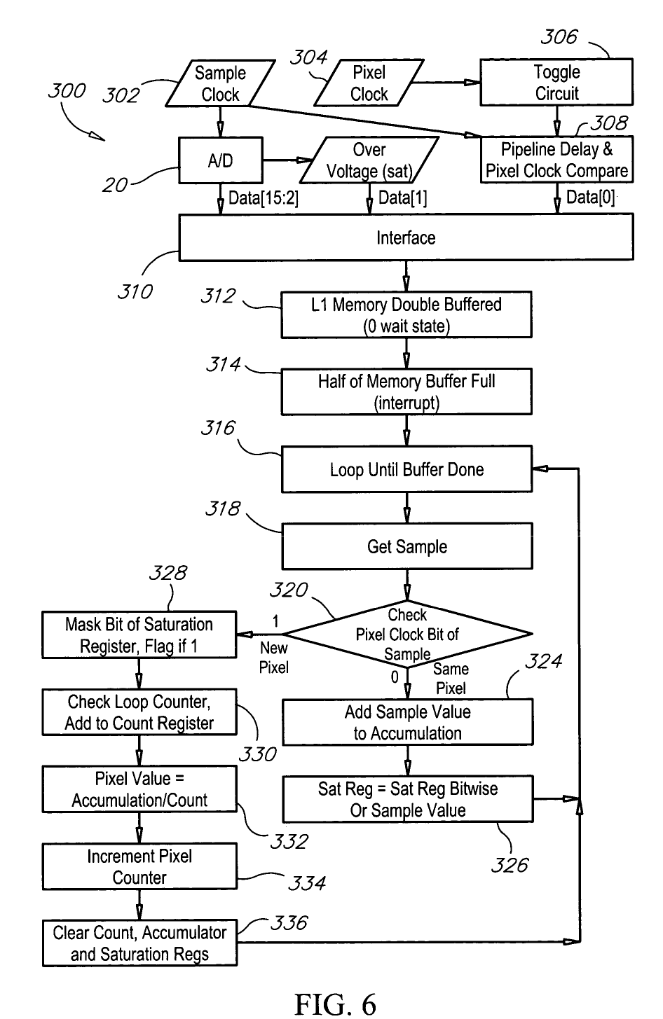

Referring now to FIG. 6, a data flow diagram 300 is shown to describe processing precision, high speed scanning signals by the present system. Sample clock 302 is inputted to the A/D converter(s) and the DSP. Clock 302 thus tells the A/D converter(s) when to take samples, and also tells the DSP when to read samples form the A/D converter. As a non-limiting example, the clock rate of clock 302 may be 65 MHz, as noted above. In this example, the A/D converter 20 is a pipelined converter, so that there is an eight clock cycle delay from the input to the converter 20 until that input is outputted. Accordingly, pixel clock 304 is on an eight clock cycle delay circuit so that it is timed accurately with the digitized data being outputted from A/D converter 20. Of course, other delay lengths may be implemented by the pipeline without varying from the spirit of the invention. Also, an AID converter that is not pipelined may be used, but this would reduce overall processing speeds.

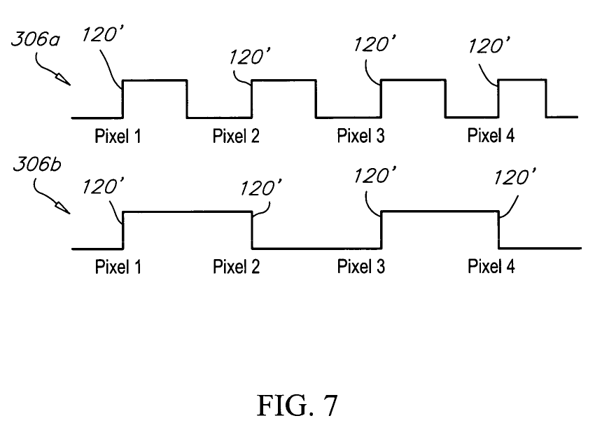

A toggle circuit 306 may be implemented to convert the pixel clock signal from the square wave 306a to the square wave 306b, as shown in FIG. 7. By converting to the waveform 306b, the detection of each pixel transition is made faster, since the system only has to recognize each transition of the signal (i.e., from 0 to 1 or from 1 to 0) to identify the transition from one pixel to the next.

At 308, the pixel clock signals are compared by a circuit that looks for any state transition of the signal 306b and outputs a pulse that is one sample clock wide when a state transition is detected. The circuit runs according to the sample clock and compares the last (current) stage of the pipeline to the stage preceding it. There is a pipeline delay to the pixel clock to account for the delay of the pipeline in sending the information to the AID converter. For example, for a pipeline having a delay of eight sample clock signals, the pixel clock will be delayed by eight sample clocks so as to be synchronized with the digitized data that is outputted from A/D 20 as both are inputted to the DSP. Additionally, the saturation level is monitored from line 22 that is connected to A/D converter, since the A/D converter outputs a signal when a sample signal is determined to be saturated.

An interface 310 is provided between the A/D converter 20 and the DSP, and may be built in as a part of the DSP, for example, for input of the digital signals converted by AID converter. For example, a 16 bit DMA Interface for Analog Devices Blackfin Architecture BF533 DSP or BF561 DSP, or the like may be employed.

Interface 310 routes the data to a double buffered memory 312 which may have a zero wait state (i.e., the data gets put into memory at the system clock rate). As the digitized signal data, saturation data and pixel clock data are flowing into the first buffer (e.g., Buffer 1), the capacity of the first buffer is monitored. When Buffer 1 is full, the data flow is diverted to Buffer 2 to begin filling it. Also, when Buffer 1 has been filled, an interrupt may be processed at event 314 to initiate a subroutine 316 to begin processing the data in Buffer 1. The DSP can be set up to run a double (or more) buffer system. All that needs to be done is to set up the registers correctly, and switching from one buffer to the next is performed automatically by the DSP. For each loop of subroutine 316, a sample signal is processed by the DSP (i.e. a signal received over one sample clock period).

First the pixel clock bit of the sample is checked at event 320. If the pixel clock bit is 1 ( for a signal characterized like signal 120′b described above, or alternatively, the pixel clock may be checked for any transition between 1 and 0 or 0 and 1, if a signal such as 120a′ is used, as described above) then the current data sample belongs to a new pixel and processing begins to evaluate the next pixel. On the other hand, if the pixel clock bit is zero or alternatively, no transition has occurred), then the sample value is accumulated at event 324 in an accumulation register, as this data belongs to the same pixel that is currently being processed. At event 326, the overvoltage bit of the current sample (i.e., that received through line 22) is compared via a BitwiseOR operation with all previous overvoltage bit values from all previous samples for the same pixel, which are accumulated in a saturation register. Thus, if any sample signal within a pixel is indicated to be saturated by the presence of an overvoltage bit value of 1, then the value for the saturation bit will be 1. That is, the saturation register does a BitwiseOR operation of all sample bits for each sample. Since one of the bits for each sample is the saturation bit, the BitwiseOR operation includes a BitwiseOR consideration of every saturation bit. Thus, once the processing of a pixel is finished, that system need only check that one bit of the saturation register to determine if any samples were saturated (e.g., if the saturation bit has a value of one, then at least one sample was saturated). This is a very fast and efficient technique for determining whether any of the sample signals within the pixel bin have been saturated.

The processing then continues to event 316 and 318 to process the next sample signal in the manner described above. This loop continues until a new pixel is detected or until the current Buffer (Buffer 1 in this instance) has been depleted by processing all of the data contained therein. In the latter situation, the subroutine then just idles until another interrupt is received. Another interrupt will be received after the other Buffer (Buffer 2 in this instance) has been filled, upon which the data flow is re-diverted to Buffer 1, and processing from Buffer 2 proceeds.

When a new pixel is detected at event 320, then the overvoltage or saturation bit is masked, or checked, at event 328 and a flag is set if the value of the overvoltage/saturation bit is 1. Next, the loop counter of the system, which keeps a count of the number of loops/samples processed by the subroutine for the current pixel is checked and added to a count register at event 330. At event 332, the pixel value for the pixel that has just completed accumulating is calculated by dividing the accumulation value in the accumulation register by the loop count value in the count register. Note that if a flag was generated at event 328, then the accumulation value of the accumulation register from the alternate gain channel 2 is used, since these values will not have been saturated.

At event 334, a pixel counter of the system, which numbers and tracks the number of pixels processed, is incremented. At event 336, the count register, accumulation registers (for both the primary gain channel 1 and alternate gain channel 2), and saturation registers (for both the primary gain channel 1 and alternate gain channel 2) are cleared, and processing returns to event 316 to begin processing samples for the next pixel.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

That which is claimed is:

1. A method of converting a data stream from a precision, high speed scan process into pixel data and accurately locating the pixel data relative to the substrate that was scanned, wherein the substrate is scanned to provide sample signals at a high rate of sampling to form the data stream, said method comprising the steps of:
inputting a first or next sample signal from the data stream into an A/D converter and converting the first or next sample signal into a first or next digitized sample signal;
inputting the first or next digitized sample signal and a pixel clock signal, in parallel into a digital signal processor, wherein the pixel clock signal is adapted to characterize the location of the sample signal relative to the substrate from which it was taken by indicating the transition from one pixel to a next pixel;
storing the sample signal and pixel clock signal data in digital format as outputted by the AID converter into a first or second buffer associated with a digital signal processor;
repeating said inputting a next sample signal, inputting a pixel clock signal and storing steps until a predetermined percentage of the first or second buffer has been filled;
diverting output from the AID converter to the other of the first or second buffer, and carrying out said inputting a next sample signal, inputting a pixel clock signal, storing and repeating steps, while, at the same time, processing the stored sample signal and pixel clock digital data stored in the other of the first or second buffers, with the digital signal processor.

2. The method of claim 1, wherein said processing with the digital signal processor is carried out in real time, during scanning.

3. The method of claim 1, further comprising outputting a signal from the A/D converter to the first or second buffer, concurrently with each output of a sample signal and pixel clock signal data in digital format, to indicate whether the concurrently outputted sample signal is saturated.

4. The method of claim 1, further comprising carrying out the steps in claim 1 with regard to a second A/D converter, simultaneously with carrying out said steps in claim 1, wherein the second A/D converter has a higher range of signal intensity processing capability that of the A/D converter recited in claim 1.

5. The method of claim 4, further comprising outputting a signal from the A/D converter recited in claim 1, to the first or second buffer, concurrently with each output of a sample signal and pixel clock signal data in digital format, to indicate whether the concurrently outputted sample signal is saturated; and wherein, during said processing by the digital signal processor, when any sample signal is associated with a signal indicating that the sample is saturated, the digital signal processor processes alternative samples outputted from the second A/D converter, relative to all sample signals from the first A/D converter within the pixel including the sample signal with the associated signal indicating that the sample is saturated.

6. The method of claim 1, wherein the substrate includes at least one microarray thereon.

7. A method comprising forwarding a result obtained from the method of claim 1 to a remote location.

8. A method comprising transmitting data representing a result obtained from the method of claim 1 to a remote location.

9. A method comprising receiving a result obtained from a method of claim 1 from a remote location.

10. A method of converting a data stream from a precision, high speed scan process into pixel data and accurately locating the pixel data relative to the substrate that was scanned, wherein the substrate is scanned to provide sample signals at a high rate of sampling to form the data stream, said method comprising the steps of:
inputting a first or next sample signal from the data stream into an AID converter and converting the first or next sample signal into a first or next digitized sample signal;
inputting the first or next digitized sample signal and a pixel clock signal, in parallel, into a DSP, wherein the pixel clock signal is adapted to characterize the location of the sample signal relative to the substrate from which it was taken by indicating the transition from one pixel to a next pixel;
storing the sample signal and pixel clock signal data in digital format as inputted into a buffer associated with a digital signal processor;
repeating said inputting and converting a next sample signal, inputting said digitized next sample and a pixel clock signal and storing steps until scanning of the substrate has been completed; and
analyzing the stored sample and pixel clock signals by the DSP offline, after scanning has been completed.

11. A system for converting a data stream from a precision, high speed scan process into pixel data and accurately locating the pixel data relative to the substrate that was scanned, wherein the substrate is scanned to provide sample signals at a high rate of sampling to form the data stream, said system comprising:
an A/D converter for high-rate sampling the data stream and converting the samples into digitized sample signals;
a pixel clock configured to output a pixel clock signal, in parallel with the digitized sample signals, wherein the pixel clock signal is adapted to characterize the location of the sample signal relative to the substrate from which it was taken by indicating the transition from one pixel to a next pixel;
means for storing the sample signal and pixel clock signal data in digital format, wherein the pixel clock signal data is encoded with the sample signal data; and
a DSP for analyzing the sample signal data and pixel clock signal data stored in said means for storing.

12. The system of claim 11, wherein said means for storing is a single large buffer and said DSP analyzes the sample signal data and pixel clock signal data offline, after completion of scanning of the substrate and storage of said sample signal data and pixel clock signal data.

13. The system of claim 11, wherein said means for storing comprises first and second buffers and said DSP analyzes said sample signal data and pixel clock signal data in real time, during scanning of the substrate.

14. The system of claim 11, wherein said means for storing comprises first and second buffers, said system further comprising means for diverting digitized signals and pixel clock signals from said first to said second buffer and vice versa, while, at the same time, processing the stored sample signal and pixel clock digital data stored in the other of the first or second buffers, with the DSP.

15. The system of claim 11, further comprising means for determining whether a sampled signal is within the dynamic range of the A/D converter, and means for outputting a signal to indicate whether the concurrently outputted sample signal is saturated.

16. The system of claim 15, further comprising a second A/D converter, wherein, when it is determined that a sample signal saturates the first A/D converter, the same sample signal is converted by the second AID converter to be used for analysis by said DSP.

17. A computer readable medium carrying one or more sequences of instructions for converting a data stream from a precision, high speed scan process into pixel data and accurately locating the pixel data relative to the substrate that was scanned, wherein the substrate is scanned to provide sample signals at a high rate of sampling to form the data stream, wherein execution of one or more sequences of instructions by one or more processors causes the one or more processors to perform the steps of:
inputting a first or next sample signal from the data stream into an A/D converter and converting the first or next sample signal into a first or next digitized sample signal;
inputting the first or next digitized sample signal and a pixel clock signal, in parallel into a DSP, wherein the pixel clock signal is adapted to characterize the location of the sample signal relative to the substrate from which it was taken by indicating the transition from one pixel to a next pixel;
storing the sample signal and pixel clock signal data in digital format as outputted by the A/D converter into a first or second buffer associated with a digital signal processor;
repeating said inputting a next sample signal, inputting a pixel clock signal and storing steps until a predetermined percentage of the first or second buffer has been filled;
diverting output from the A/D converter to the other of the first or second buffer, and carrying out said inputting a next sample signal, inputting a pixel clock signal, storing and repeating steps, while, at the same time, processing the stored sample signal and pixel clock digital data stored in the other of the first or second buffers, with the digital signal processor.

18. The computer readable medium of claim 17, wherein said execution of one or more sequences of instructions causes the one or more processors to perform the further step of outputting a signal from the A/D converter to the first or second buffer, concurrently with each output of a sample signal and pixel clock signal data in digital format, to indicate whether the concurrently outputted sample signal is saturated.

19. The computer readable medium of claim 17, wherein said processing with the digital signal processor is carried out in real time, during scanning.

20. The computer readable medium of claim 18, wherein said execution of one or more sequences of instructions causes the one or more processors to perform the further steps of carrying out the steps in claim 18 with regard to a second A/D converter, simultaneously with carrying out said steps in claim 1, wherein the second A/D converter has a higher range of signal intensity processing capability that that of the A/D converter recited in claim 18.
